(19) United States
(12) Patent Application Publication
(10) Pub. No.: US 2026/0312273 A1
(43) Pub. Date: Oct. 8, 2026

(54) ELECTRONIC DEVICES AND METHODS OF MANUFACTURING ELECTRONIC DEVICES

(71) Applicant: Amkor Technology Singapore Holding Pte. Ltd., Valley Point (SG)

(72) Inventors: Byung Ho KIM, Seoul (KR); Tae Yong LEE, Gyeonggi-do (KR); Jeong Hyun YANG, Seoul (KR); Min Won PARK, Incheon (KR); Kun Hee LEE, Incheon (KR)

(73) Assignee: Amkor Technology Singapore Holding Pte. Ltd., Valley Point (SG)

(21) Appl. No.: 19/169,123

(22) Filed: Apr. 3, 2025

(51) Int. Cl. H01Q 1/22; H01L 23/31; H05K 1/16; H05K 1/18; H05K 3/28

(52) U.S. Cl. CPC H01Q 1/2283; H05K 1/16; H05K 1/185; H05K 3/284; H05K 2201/10098; H10W 74/111

(57) ABSTRACT

In one example, an electronic device includes a substrate including a first side and a second side. An antenna structure includes antenna feed structures connected to the first side and antenna patterns. An encapsulant covers the antenna feed structures and the first side and includes an outer side and a recess extending inward from the outer side. The recess includes a lower side below the outer side. The antenna feed structures includes first and second antenna feed structures. The antenna patterns include a first antenna pattern adjacent to the lower side and connected to the first antenna feed structure and a second antenna pattern adjacent to the outer side and coupled to the second antenna feed structure. Electronic components are connected to the substrate at the second side and are coupled to the antenna feed structures. Other examples and related methods are also disclosed herein.

### CROSS-REFERENCES TO RELATED APPLICATIONS

Not applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, for example resulting in excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A, 2B, 2C, 2D, and 2E show cross-sectional views of an example method for manufacturing an example electronic device.

FIG. 3 shows a cross-sectional view of an example electronic device.

FIGS. 4A, 4B, 4C, 4D, and 4E show cross-sectional views of an example method for manufacturing an example electronic device.

FIG. 5 shows a cross-sectional view of an example electronic device.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. Elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. Unless specified otherwise, the term “coupled” can refer to a mechanical coupling or electrical coupling.

### DESCRIPTION

Wireless and portable handheld communication applications are examples of applications continuing to grow and evolve with an increased effort to integrate more electronic functionality into smaller, lighter, thinner, and lower cost solutions. One of the continuing challenges for these applications is the improvement and integration of effective antennas, such as multi-band antennas into the various product platforms to support applications, such 5G NR millimeter wave (mmWave) and sub-6 GHz RF modules for smartphones or other mobile devices. Such platforms can include, for example, antenna-in-package (AiP) or antenna-on-package (AoP) configurations.

The present description includes, among other features, structures and associated methods that relate to electronic devices using integrated antenna structures, such as multi-band AiP or AoP structures. More particularly, structures and methods are described that include a recessed or stepped encapsulant structure to support multiple bands in a single package structure. The methods and structures provide improved grounding, improved beam control, and better separation between the bands. In addition, the structures and methods of the present description incorporate existing manufacturing techniques, which saves on costs.

In an example, an electronic device includes a substrate including a substrate first side, a substrate second side opposite to the substrate first side, and a conductive structure. An antenna structure includes antenna feed structures coupled to the substrate first side and antenna patterns each coupled to one of the antenna feed structures. A top encapsulant covers the antenna feed structures and the substrate first side and includes a top encapsulant outer side and a first recess extending inward from the top encapsulant outer side. The first recess includes a first recess lower side below the top encapsulant outer side. The antenna feed structures comprise a first antenna feed structure and a second antenna feed structure. The antenna patterns include a first antenna pattern adjacent to the first recess lower side and coupled to the first antenna feed structure and a second antenna pattern adjacent to the top encapsulant outer side and coupled to the second antenna feed structure. Electronic components are coupled to the substrate at the substrate second side and coupled to the antenna feed structures.

In an example, an electronic device includes a substrate including a substrate first side, a substrate second side opposite to the substrate first side, a dielectric structure, and a conductive structure within the dielectric structure. A plurality of antenna feed structures are coupled to the conductive structure at the substrate first side and include a first antenna feed structure, a second antenna feed structure, and a third antenna feed structure. A top encapsulant covers the plurality of antenna feed structures and the substrate first side and includes a top encapsulant outer side and a plurality of recessed regions extending inward from the top encapsulant outer side and comprising a first recessed region comprising a first lower side, a second recessed region comprising a second lower side, and a third recessed region comprising a third lower side. A plurality of antenna patterns includes a first antenna pattern adjacent to the first lower side and coupled to the first antenna feed structure, a second antenna pattern adjacent to the second lower side and coupled to the second antenna feed structure, a third antenna pattern adjacent to the third lower side and coupled to the third antenna feed structure. Electronic components are coupled to the conductive structure at the substrate second side. A bottom encapsulant covers the electronic components and the substrate second side.

In an example, a method of manufacturing an electronic device includes providing a substrate including a substrate first side, a substrate second side opposite to the substrate first side, a dielectric structure, and a conductive structure within the dielectric structure. The method includes providing a plurality of antenna feed structures coupled to the conductive structure at the substrate first side and comprising a first antenna feed structure, a second antenna feed structure, and a third antenna feed structure. The method includes providing a top encapsulant covering the plurality of antenna feed structures and the substrate first side and including a top encapsulant outer side and a plurality of recessed regions extending inward from the top encapsulant outer side and comprising a first recessed region comprising a first lower side, a second recessed region comprising a second lower side, and a third recessed region comprising a third lower side. The method includes providing a plurality of antenna patterns comprising a first antenna pattern adjacent to the first lower side and coupled to the first antenna feed structure, a second antenna pattern adjacent to the second lower side and coupled to the second antenna feed structure, a third antenna pattern adjacent to the third lower side and coupled to the third antenna feed structure. The method includes providing electronic components coupled to the conductive structure at the substrate second side. The method includes providing a bottom encapsulant covering the electronic components and the substrate second side.

Other examples are included in the present disclosure. Such examples may be found in the figures, in the claims, or in the description of the present disclosure.

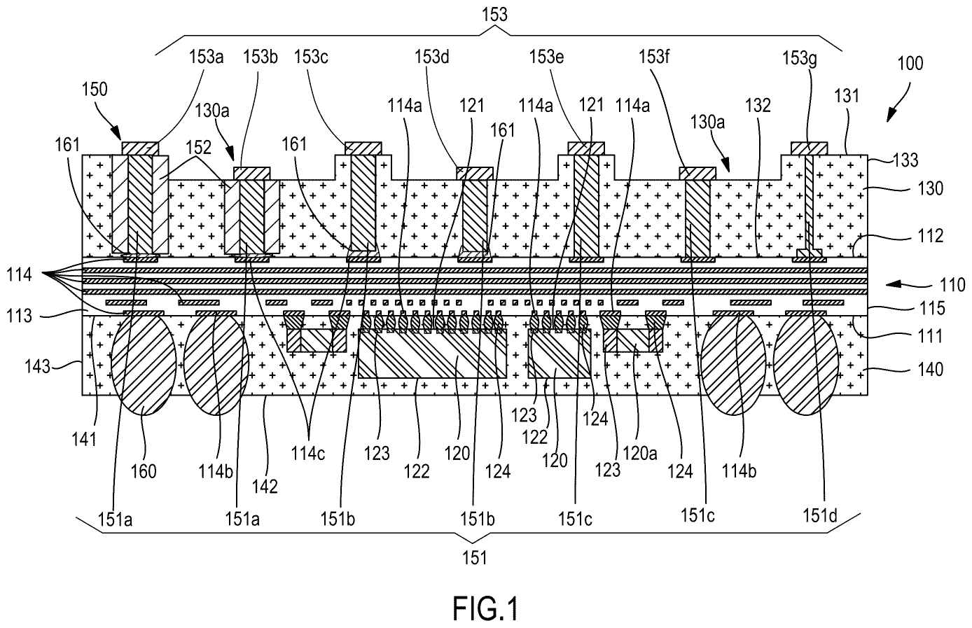

FIG. 1 shows a cross-sectional view of example electronic device 100. In the present example, electronic device 100 is provided in an example AiP/AoP configuration. In the example shown in FIG. 1, electronic device 100 can comprise substrate 110, electronic components 120, electronic components 120a, top encapsulant 130, bottom encapsulant 140, antennas 150, and external interconnects 160. Antennas 150 can comprise are be referred to as antenna structure or antenna structures.

In some examples, substrate 110 can comprise first side 111, second side 112 opposite to first side 111, lateral side 115 connecting first side 111 to second side 112, dielectric structure 113, and conductive structure 114. Conductive structure 114 can comprise component terminals 114a, external interconnect terminals 114b, and antenna terminals 114c. First side 111 can comprise or be referred to as substrate first side and second side 112 can comprise or be referred to substrate second side.

In some examples, electronic components 120 can comprise first side 121, second side 122 opposite to first side 121, contact pads 123 adjacent to first side 121, and connectors 124 coupling electronic components 120 to component terminals 114a. In some examples, electronic components 120a can comprise contact pads 123 and connectors 124 coupling electronic components 120a to component terminals 114a.

Top encapsulant 130 is over second side 112 of substrate 110 and can comprise top encapsulant outer side 131, a top encapsulant inner side 132 opposite to top encapsulant outer side 131, and a top encapsulant lateral side 133 connecting top encapsulant outer side 131 to top encapsulant inner side 132. In the present example, top encapsulant outer side 131 is distal to second side 112 of substrate 110 and top encapsulant inner side 132 is proximate to second side 112 of substrate 110. In the present example, top encapsulant 130 comprises a thickness that varies across its lateral width. In accordance with the present description, this variation in thickness is determined based on the operating frequency of different antennas 150 of electronic device 100. In some examples, recesses 130a can be provided extending inward from top encapsulant outer side 131 so that top encapsulant 130 comprises thin and thick portions of various degrees. In the present example each of recesses 130a comprise a lower side that is lower than top encapsulant outer side 131. It is understood that the lower sides of recesses 130a can be at different locations and comprise different depths below top encapsulant outer side 131. Recesses 130a are an example of a plurality of recessed regions extending inward from top encapsulant outer side 131.

In some examples, external interconnects 160 are coupled to external interconnect terminals 114b adjacent to first side 111 of substrate 110. In some examples, bottom encapsulant 140 is adjacent to first side 111 of substrate 110 and can cover electronic components 120, electronic components 120a, exposed portions of second side 112 of substrate 110, and portions of external interconnects 160. Bottom encapsulant 140 can comprise bottom encapsulant inner side 141, bottom encapsulant outer side 142 opposite to bottom encapsulant inner side 141, and lateral side 143 connecting bottom encapsulant inner side 141 to bottom encapsulant outer side 142. In the present example, bottom encapsulant inner side 141 is adjacent to first side 111 of substrate 110 and bottom encapsulant outer side 142 is distal to first side 111 of substrate 110. In the present example, portions of external interconnects 160 are exposed from bottom encapsulant outer side 142 and protrude outward (for example, downward or upward depending on the orientation of electronic device 100) from bottom encapsulant outer side 142, which is located inward with respect to the lower end regions of external interconnects 160.

Antennas 150 can comprise antenna feed structures 151 and antenna patterns 153. In some examples, antenna patterns 153 are over top encapsulant outer side 131 or within recesses 130a of top encapsulant 130. In the present example, antenna feed structures 151 can comprise different configurations, including, but not limited to, molded antenna feed structures 151a, which are covered by dielectric 152, preformed pillar antenna feed structures 151b, plated pillar antenna feed structures 151c, or conductive wire antenna feed structure 151d. In some examples, proximate ends of antenna feed structures 151 are coupled to antenna terminals 114c adjacent to second side 112 of substrate 110. In some examples, proximate ends of molded antenna feed structures 151a or preformed pillar antenna feed structures 151b are coupled to antenna terminals 114c with conductive interface material 161, such as a solder. Antenna feed structures 151 are configured to transceive signals between electronic components 120, electronic components 120a, and antenna patterns 153 through conductive structure 114 of substrate 110.

In the present example, electronic device 100 can be provided with separate antenna patterns 153 including, for example, antenna pattern 153a, antenna pattern 153b, antenna pattern 153c, antenna pattern 153d, antenna pattern 153e, antenna pattern 153f, and antenna pattern 153g. It is understood that antenna patterns 153 can extend into or out of the cross-sectional view of FIG. 1 and the patterns can be the same or different depending on the frequency of operation requirements of electronic device 100.

In some examples, top encapsulant 130 covers lateral or side portions of antenna feed structures 151 (or dielectric 152 of molded antenna feed structure 151a) and distal ends of antenna feed structures 151 can be exposed from top encapsulant outer side 131 and coupled to antenna patterns 153. In some examples, each antenna feed structure 151 is coupled to a separate one of antenna patterns 153 (for example, antenna patterns 153a, 153b, 153c, 153d, 153e) to provide a multi-band antenna configuration.

Substrate 110, top encapsulant 130, bottom encapsulant 140, and external interconnects 160 can be referred to as a semiconductor package, and the package can protect electronic components 120, electronic components 120a, and antenna feed structures 151 from external elements and/or external exposure. The semiconductor package can provide electrical coupling between electronic components 120, electronic components 120a, and antennas 150 and between electronic device 100 and external electronic components.

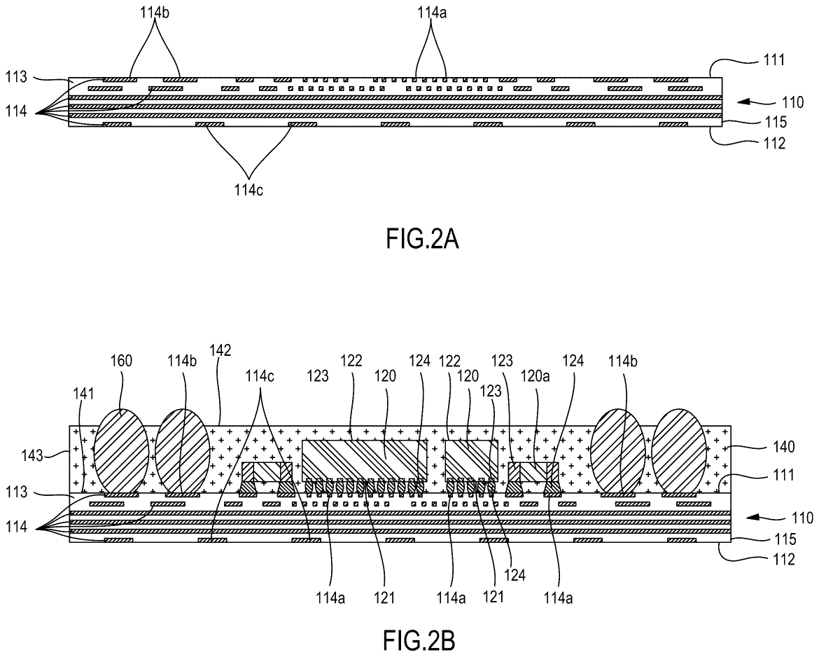

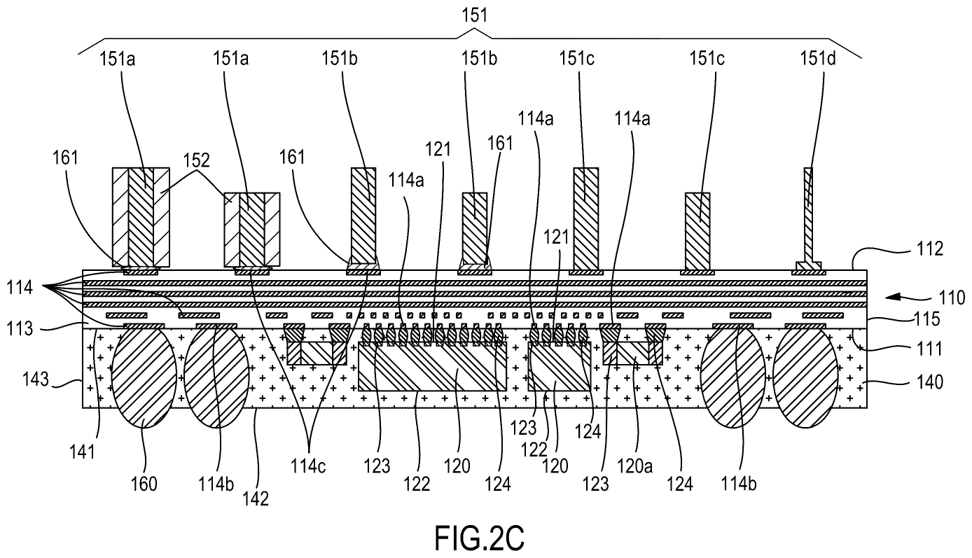

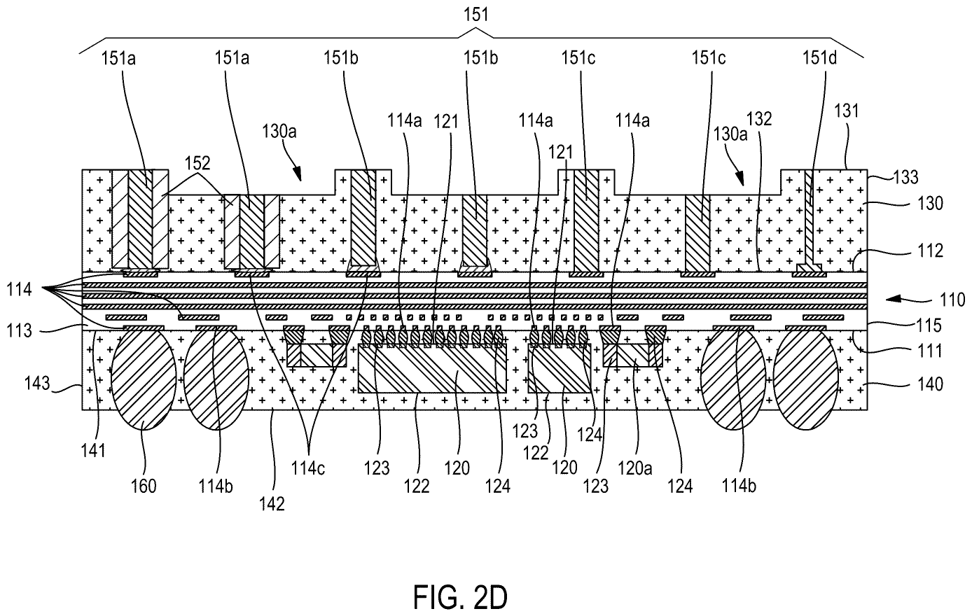

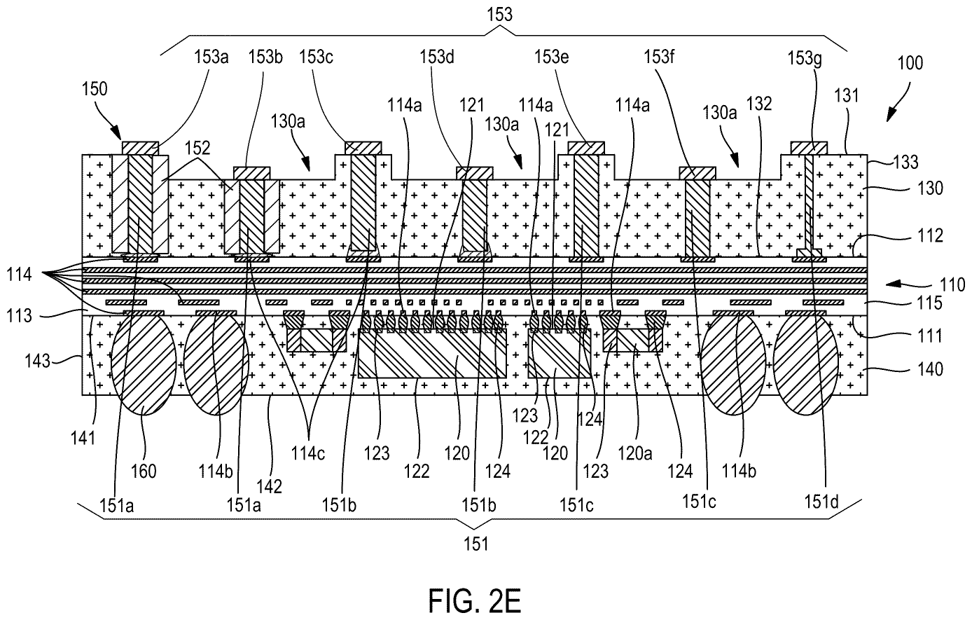

FIGS. 2A, 2B, 2C, 2D, and 2E show cross-sectional views of an example method for manufacturing an electronic device including, for example, electronic device 100.

FIG. 2A shows a cross-sectional view of electronic device 100 at an early stage of manufacture. In the example shown in FIG. 2A, substrate 110 can be provided. In some examples, substrate 110 can comprise first side 111, second side 112 opposite to first side 111, lateral side 115 connecting first side 111 to second side 112, dielectric structure 113 between first side 111 and second side 112, and conductive structure 114 between first side 111 and second side 112. First side 111 can be the lower side (or upper side) of dielectric structure 113. Second side 112 can be the upper side (or lower side) of dielectric structure 113.

Dielectric structure 113 can comprise one or more dielectric material layers interleaved between layers of conductive structure 114. Dielectric structure 113 can comprise or be referred to as a dielectric, an insulator, or a passivation. In some examples, dielectric structure 113 can comprise polyimide (PI), benzocyclobutene (BCB), polybenzoxazole (PBO), resin, an Ajinomoto buildup film (ABF), epoxy, or ceramic.

Conductive structure 114 can comprise one or more conductive layers defining signal distribution elements. The signal distribution elements can comprise or be referred to as traces, vias, pads, conductive paths, and under bumped metal (UBM). In some examples, conductive structure 114 can comprise copper, a copper alloy, aluminum, an aluminum alloy, gold, a gold alloy, silver, a silver alloy, nickel, a nickel alloy, palladium, a palladium alloy, tin-silver, combinations thereof, or other conductive materials as known to one of ordinary skill in the art.

In some examples, conductive structure 114 can comprise component terminals 114a. Component terminals 114a can be exposed at first side 111 of substrate 110. Electronic components 120 and electronic components 120a can be subsequently coupled to component terminals 114a. Component terminals 114a can comprise or be referred to as pads, lands, UBMs, or studs. Conductive structure 114 can comprise external interconnect terminals 114b exposed at first side 111 and to which external interconnects 160 can be subsequently coupled. External interconnect terminals 114b can comprise or be referred to as pads, lands, UBM, or studs. Conductive structure 114 can further comprise antenna terminals 114c exposed at the second side 112 of substrate 110. Antennas 150 can be subsequently coupled to antenna terminals 114c. Conductive structure 114 provides electrical interconnect horizontally and vertically through dielectric structure 113. Conductive structure 114 can provide electrical interconnection between component terminals 114a, external interconnect terminals 114b, and antenna terminals 114c.

In some examples, the exposed area of component terminals 114a or external interconnect terminals 114b can be coplanar with first side 111 of dielectric structure 113. In other examples, the exposed area of component terminals 114a or external interconnect terminals 114b can be at a location different from (for example, above or below) first side 111.

In some examples, the overall thickness of substrate 110 can range from approximately 10 μm to approximately 2000 μm. In this way, substrate 110 comprising dielectric structure 113 and conductive structure 114 can be configured to support electronic components 120, electronic components 120a, and antennas 150 while interconnecting electronic components 120, electronic components 120a, and antennas 150 to an external device.

In some examples, substrate 110 can be a pre-formed (or laminate) substrate. Pre-formed substrates can be manufactured prior to attachment to an electronic device and can comprise dielectric layers between respective conductive layers. In some examples, the conductive layers can comprise copper and can be formed using an electroplating process. The dielectric layers can be relatively thicker non-photo-definable layers and can be attached as a pre-formed film rather than as a liquid and can include a resin with fillers such as strands, weaves, or other inorganic particles for rigidity or structural support. Since the dielectric layers are non-photo-definable, features such as vias or openings can be formed by using a drill or laser. In some examples, the dielectric layers can comprise a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate omitting the permanent core structure, and the dielectric and conductive layers can be formed on a sacrificial carrier that is removed after formation of the dielectric and conductive layers and before attachment to the electronic device. The pre-formed substrate can be referred to as a printed circuit board (PCB) or a laminate substrate. Such pre-formed substrates can be formed through a semi-additive or modified-semi-additive process.

In some examples, substrate 110 can be a redistribution layer (“RDL”) substrate. RDL substrates can comprise one or more conductive redistribution layers and one or more dielectric layers that (a) can be formed layer by layer over an electronic device to which the RDL substrate is to be coupled, or (b) can be formed layer by layer over a carrier that can be entirely removed or at least partially removed after the electronic device and the RDL substrate are coupled together. RDL substrates can be manufactured layer by layer as a wafer-level substrate on a round wafer in a wafer-level process, or as a panel-level substrate on a rectangular or square panel carrier in a panel-level process. RDL substrates can be formed in an additive buildup process that can include one or more dielectric layers alternatingly stacked with one or more conductive layers that define respective conductive redistribution patterns or traces configured to collectively (a) fan-out electrical traces outside the footprint of the electronic device, and/or (b) fan-in electrical traces within the footprint of the electronic device. The conductive patterns can be formed using a plating process such as, for example, an electroplating process or an electroless plating process. The conductive patterns can comprise an electrically conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, which can include a photolithographic mask through which light is exposed to photo-pattern desired features such as vias in the dielectric layers. Thus, the dielectric layers can be made from photo-definable organic dielectric materials such as, for example, polyimide (PI), benzocyclobutene (BCB), polybenzoxazole (PBO), resin or ABF (Ajinomoto Build-up Film). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles, which could interfere with the light from the photo-patterning process. In some examples, such filler-free characteristics of filler-free dielectric materials can permit a reduction of the thickness of the resulting dielectric layer. Although the photo-definable dielectric materials described above can be organic materials, in other examples the dielectric materials of the RDL substrates can comprise one or more inorganic dielectric layers. Some examples of inorganic dielectric layer(s) can comprise silicon nitride (Si₃N₄), silicon oxide (SiO₂), and/or silicon oxynitride SiON. The inorganic dielectric layer(s) can be formed by growing the inorganic dielectric layers using an oxidation or nitridization process instead using photo-defined organic dielectric materials. Such inorganic dielectric layers can be filler-fee, without strands, weaves, or other dissimilar inorganic particles. In some examples, the RDL substrates can omit a permanent core structure (e.g., a dielectric core comprising bismaleimide triazine (BT) or FR4) that is generally associated with pre-formed laminate substrates.

FIG. 2B shows a cross-sectional view of electronic device 100 at a later stage of manufacture. In the example shown in FIG. 2B, electronic components 120 can be provided on first side 111 of substrate 110. In some examples, electronic components 120 can be coupled to conductive structure 114 of substrate 110. For example, electronic components 120 can be coupled to component terminals 114a with connectors 124.

In some examples, electronic components 120 can comprise or be referred to as one or more dies, chips, or packages. In some examples, electronic components 120 can comprise a memory, a digital signal processor (DSP), a microprocessor, a network processor, a power management processor, an audio processor, an RF circuit, a wireless baseband system-on-chip (SoC) processor, a sensor, or an application specific integrated circuit (ASIC). Electronic components 120 can be of variable size.

Electronic components 120 comprise first sides 121 and second sides 122 opposite to first sides 121. In some examples, first sides 121 can comprise active sides and second sides 122 can be active sides or inactive sides.

In some examples, electronic components 120 can comprise contact pads 123 over first sides 121 and connectors 124 coupling contact pads 123 to component terminals 114a. Contact pads 123 can be provided adjacent to first sides 121 of electronic components 120 and spaced apart from each other in a row or column direction. Contact pads 123 can be referred to as bond pads, pads, or UBMs pads and can be exposed through an inorganic material (for example, SiO₂ or Si₃N₄), or redistribution layer (RDL) pads exposed through a dielectric layer.

In some examples, connectors 124 can comprise or be referred to as component interconnects, component terminals, bumps, pillars, pads, or solder balls. Connectors 124 can be provided as electrical contacts between electronic components 120 and substrate 110. Connectors 124 can be coupled to conductive structure 114. For example, connectors 124 can be coupled to component terminals 114a of conductive structure 114 by a mass reflow process, a thermal compression process, or a laser bonding process. In some examples, connectors 124 can comprise copper (Cu), lead (Pb), tin (Sn), aluminum (Al), palladium (Pd), titanium (Ti), tungsten (W), titanium/tungsten (Ti/W), nickel (Ni), gold (Au), or silver (Ag) In other examples, connectors 124 can be provided on first sides 121 of electronic components 120 by electroplating, electroless plating, sputtering, PVD, CVD, MOCVD, ALD, LPCVD, or PECVD. For example, after providing a photoresist pattern for exposing contact pads 123 of electronic components 120, connectors 124 can be provided to contact exposed contact pads 123 on first sides 121 of electronic components 120. In some examples, the thickness of connectors 124 can range from about 1 μm to about 2 μm, and the width and pitch of connectors 124 can range from about 5 μm to about 10 μm.

In some examples, pick-and-place equipment can pick up electronic components 120 and place electronic components 120 on first side 111 of substrate 110. Connectors 124 of electronic components 120 can be located on component terminals 114a of substrate 110. In some examples, the overall thickness of electronic components 120 can range from about 0.3 mm to about 9 mm, and the area of electronic components 120 can range from about 0.5 mm×0.5 mm to about 70 mm×70 mm.

In some examples, electronic components 120a can be provided on first side 111 of substrate 110. Electronic components 120a can comprise contact pads 123 and connectors 124. In some examples, electronic components 120a, contact pads 123, and connectors 124 can have corresponding elements, features, materials or manufacturing methods similar to those of electronic components 120. Electronic components 120a can comprise or be referred to as a die, a chip, a package, or a passive element. For example, electronic components 120a can comprise capacitors, resistors, or inductors. In some examples, electronic components 120a can comprise active die or packages containing active and/or passive devices In some examples, the thickness of electronic components 120a can range from about 50 μm to about 2000 μm. Electronic components 120a can be attached to substrate 110 in a similar as described for attaching electronic components 120.

External interconnects 160 can be coupled to external interconnect terminals 114b of conductive structure 114. In some examples, external interconnects 160 can comprise solder balls, bumps, pillars, posts, solder coated copper core balls, wire, or any other suitable interconnection structure. The width of external interconnects 160 can range from approximately 0.01 mm to approximately 10 mm. External interconnects 160 can be configured to couple electronic device 100 to a next level of assembly or an external device.

Bottom encapsulant 140 can be provided over first side 111 of substrate 110, electronic components 120, electronic components 120a, and external interconnects 160. Bottom encapsulant 140 can cover and/or contact first side 111 of substrate 110, electronic components 120, electronic components 120a, and external interconnects 160. Bottom encapsulant 140 can comprise bottom encapsulant inner side 141, bottom encapsulant outer side 142 opposite to bottom encapsulant inner side 141, and lateral side 143 connecting bottom encapsulant inner side 141 to bottom encapsulant outer side 142. In the present example, bottom encapsulant inner side 141 is adjacent to first side 111 of substrate 110 and bottom encapsulant outer side 142 is distal to first side 111 of substrate 110. In the present example, portions of external interconnects 160 are exposed from bottom encapsulant outer side 142 and protrude outward (for example, downward or upward depending on the orientation of electronic device 100) from bottom encapsulant outer side 142.

Bottom encapsulant 140 can comprise or be referred to as an epoxy molding compound, a resin, a filler-reinforced polymer, a B-stage compression film, or a gel. In some examples, portions of external interconnects 160 can be exposed or protrude outward from bottom encapsulant 140. In some examples, bottom encapsulant 140 can completely cover electronic components 120 and electronic components 120a so that electronic components 120 and electronic components 120a are not exposed from bottom encapsulant 140. In other examples, one or more of electronic components 120 or electronic components 120a can be exposed bottom encapsulant outer side 142. In some examples, example, second side 122 of one or more electronic components 120 can be exposed from and substantially coplanar with bottom encapsulant outer side 142. The thicknesses of bottom encapsulant 140 can range from approximately 0.02 mm to approximately 10 mm. Bottom encapsulant 140 can protect electronic components 120, electronic components 120a, or external interconnects 160 from external environments.

FIG. 2C shows a cross-sectional view of electronic device 100 at a later stage of manufacture. In the example shown in FIG. 2C, antenna feed structures 151 can be provided and coupled to conductive structure 114 at second side 112 of substrate 110.

In the present example, various structures are described for antenna feed structures 151 including molded antenna feed structures 151a, which are covered by a dielectric 152, preformed pillar antenna feed structures 151b, plated pillar antenna feed structures 151c, or conductive wire antenna feed structures 151d.

In the present example, molded antenna feed structures 151a comprise a conductive feed portion embedded within or laterally surrounded or covered by dielectric 152 with opposing end surfaces exposed from dielectric 152. In some examples, molded antenna feed structures 151a can be provided by forming conductive structures, such as copper columns pillars, elongate pillars, plated pillars, or elongate plated pillars, on a temporary carrier, providing a molded encapsulant around the conductive structures, removing the temporary carrier, and singulating the molded conductive structures. In some examples, dielectric 152 can comprise or be referred to as a molding or an encapsulant. For example, dielectric 152 can comprise a mold, such as an epoxy mold compound (EMC), a resin, a filler-reinforced polymer, a B-stage pressed film or a gel, and an organic or inorganic dielectric material. Dielectric 152 can be provided by compression molding, transfer molding, liquid body molding, vacuum lamination, paste printing, or film-assisted molding. Molded antenna feed structure 151a can comprise one or more feed conductors. In some examples, molded antenna feed structures 151a can be coupled to antenna terminals 114c of substrate 110 with conductive interface material 161.

In some examples, preformed pillar antenna feed structures 151b can be provided by coupling the lower end of a preformed conductive post to antenna terminals 114c of substrate 110 with conductive interface material 161. In some examples, preformed pillar antenna feed structures 151b can comprise or be referred to as copper posts or pillars.

In some examples, plated pillar antenna feed structures 151c can be provided by plating a conductive material (e.g., copper) on antenna terminals 114c to form a conductive pillar coupled to antenna terminal 114c. For example, a plating mask can be provided over second side 112 of substrate 110 can patterned to provide openings that expose antenna terminals, and then plating (for example, electroless plating or electroplating) can be used to form plated pillar antenna feed structures 151c in the openings. In other examples, plated pillar feed structures can comprise through-mold vias and can be provided after top encapsulant 130 is provided.

In some examples, conductive wire antenna feed structures 151d can comprise gold, silver, or copper wires. In some examples, conductive wire antenna feed structure 151d can be provided by ball bonding lower ends of conductive wires to antenna terminals 114c of substrate 110 and then cutting the upper end of the conductive wire.

In some examples, antenna feed structures 151 can have different heights. In some examples, a step can exist between adjacent antenna feed structures 151. In some examples, antenna feed structures 151 can be provided at laterally spaced locations from each other. In some examples, the heights of antenna feed structures 151 can range from approximately 0.01 mm to approximately 10 mm. Antenna feed structures 151 can be configured as signal pins or ground pins.

FIG. 2D shows a cross-sectional view of electronic device 100 at a later stage of manufacture. In the example shown in FIG. 2D, top encapsulant 130 can be provided.

In some examples, top encapsulant 130 can be provided over antenna feed structures 151 and second side 112 and of substrate 110. In some examples, top encapsulant 130 can cover and/or contact second side 112 of substrate 110 and antenna feed structures 151 (or dielectric 152 of molded antenna feed structure 151a). Top encapsulant 130 can comprise top encapsulant outer side 131, a top encapsulant inner side 132 opposite to top encapsulant outer side 131, and a top encapsulant lateral side 133 connecting top encapsulant outer side 131 to top encapsulant inner side 132. In the present example, top encapsulant 130 comprises a thickness that varies across its lateral width. In accordance with the present description, this variation in thickness can be determined, for example, based on the frequency of operation of different antennas 150 of electronic device 100. In some examples, recesses 130a can be provided extending inward from top encapsulant outer side 131 so that top encapsulant 130 comprises thin and thick portions. Each of recesses 130a can be recessed to the same or a different depth. Recesses 130a can comprise or be referred to as stepped recesses, stepped portions, grooves, or channels. In some examples, at least one recess 130a can be provided. In some examples, the distal ends of antenna feed structures 151a-151d can be exposed from and substantially coplanar with top encapsulant outer side 131 or the lower sides of recesses 130a as illustrated, for example, in FIG. 2D.

Top encapsulant 130 can comprise or be referred to as an epoxy molding compound, a resin, a filler-reinforced polymer, a B-stage compression film, or a gel. In some examples, the encapsulant of top encapsulant 130 and dielectric 152 of molded antenna feed structures 151a can comprise similar or different materials. In some examples, top encapsulant 130 can be provided by compression molding, transfer molding, liquid encapsulant molding, vacuum lamination, paste printing, or film-assisted molding. For example, compression molding can be a method in which a fluidic resin is supplied into a mold in advance and then electronic device 100 is placed into the mold to cure the fluidic resin, and transfer molding can be a method in which a fluidic resin is supplied from a gate (supply port) of a mold to the area around electronic device 100 and cured. In some examples, the upper profile or topography of top encapsulant 130 can be provided in-situ during the molding process. For example, the upper profile can be provided as part of the upper mold cavity. In other examples, laser thinning or photolithographic and etching/milling processes can be used to provide the upper profile of top encapsulant 130. For example, after top encapsulant 130 is provided, an etch mask can be provided and patterned to include openings where recesses 130a are to be formed. After the openings are provided, portions of top encapsulant 130 can be chemically or physically removed to form recesses 130a. In some examples, the thickness of top encapsulant 130 can range from approximately 100 μm to approximately 2000 μm and this thickness can vary across the lateral width of top encapsulant 130. In some examples, for a 28 GHz antenna pattern, the thickness of top encapsulant 130 can be about 300 microns; for a 40 GHz antenna pattern, the thickness can be about 200 microns; for a 10 GHz antenna pattern, the thickness can be about 800 microns. In an example where the 40 GHz antenna pattern and the 28 GHz antenna pattern are placed on top encapsulant 130 in an adjacent manner, the depth of recess 130a would be about 100 microns with the 40 GHz antenna pattern on the lower surface of recess 130a. In an example where the 10 GHz antenna pattern and the 28 GHz antenna pattern are placed on top encapsulant 130 in an adjacent manner, the depth of recess 130a would be about 500 microns with the 28 GHz antenna pattern on the lower surface of recess 130a. Top encapsulant 130 can integrate different antenna feed structures 151, which are spaced apart from each other, and can protect antenna feed structures 151 and substrate 110 from external environments.

FIG. 2E shows a cross-sectional view of electronic device 100 at a later stage of manufacture. In the example shown in FIG. 2E, antenna patterns 153 can be provided.

Antenna patterns 153 including, for example, antenna pattern 153a, antenna pattern 153b, antenna pattern 153c, antenna pattern 153d, antenna pattern 153e, antenna pattern 153f, or antenna pattern 153g, can be provided on top encapsulant outer side 131 of top encapsulant 130 or within recessed 130a. Antenna patterns 153 can be coupled to antenna feed structures 151. In the present example, antenna pattern 153a is coupled to an exposed distal end of molded antenna feed structure 151a at first location on top encapsulant outer side 131, antenna pattern 153b is coupled to an exposed distal end of another molded antenna feed structure 151a within a first recess 130a; antenna pattern 153c is coupled to an exposed distal end of preformed pillar antenna feed structure 151b at a second location on top encapsulant outer side 131; antenna pattern 153d is coupled to an exposed distal end of another preformed pillar antenna feed structure 151b within a second recess 130a; antenna pattern 153e is coupled to an exposed distal end of plated pillar antenna feed structure 151c at a third location on top encapsulant outer side 131; antenna pattern 153f is coupled to another plated pillar antenna feed structure 151c within a third recess 130a; and antenna pattern 153g is coupled to an exposed distal end of conductive wire antenna feed structure 151d at a fourth location on top encapsulant outer side 131.

In the present example, antenna patterns 153a, 153c, 153e, and 153d lie within a first horizontal plane generally defined by top encapsulant outer side 131 and antenna patterns 153b, 153d, and 153f lie within a second horizontal plane generally defined by the lower surfaces of recesses 130a, which is below the first horizontal plane.

In some examples, antenna patterns 153 can comprise copper, a copper alloy, aluminum, an aluminum alloy, gold, a gold alloy, silver, a silver alloy, nickel, a nickel alloy, palladium, a palladium alloy, or tin silver. In some examples, antenna patterns 153 can be provided by spraying, plating, evaporation, or sputtering. In some examples, antenna patterns 153 can be provided by spraying, plating, evaporation, or sputtering a conductive material after providing a photomask, metal mask, or stencil having a pattern is provided on top encapsulant 130. After providing antenna patterns 153, the mask or stencil can be removed from top encapsulant 130, leaving antenna patterns 153 formed in the pattern that was provided by the photomask, metal mask, or stencil. Each of antenna patterns 153a-153g can be the same or different patterns and include spiral, square, rectangular, circular, dipole, elliptical, triangular, disk sector, circular ring, ring sector, or other shapes as known to one ordinary skill in the art.

Antenna feed structures 151, including, for example, antenna feed structures 151a-151d are configured to transceive signals between electronic components 120, electronic components 120a, and antenna patterns 153a-153g through conductive structure 114 of substrate 110. In some examples, electronic device 100 can include the same antenna feed structures (for example, the antenna feed structures are one of antenna feed structures 151a-151d) or the antenna feed structures can be different (for example, any combinations selected from antenna feed structures 151a-151d).

In this way, the present disclosure can provide electronic device 100 with improved antennas 150 performance by adjusting the various lengths of ground lines, the lengths of signal lines, and the spacings of antennas 150. According to the present disclosure, the characteristics of antennas 150 can be easily adjusted by providing steps or recesses with various thicknesses in top encapsulant 130 and providing antenna patterns 153 on the respective steps or within the respective recesses. According to the present disclosure, antennas 150 can be provided while variously changing the shape or topography of top encapsulant outer side 131, thereby facilitating a design of a multi-band antenna, and making it easy to achieve inter-band separation performance and beam control.

Although electronic device 100 is illustrated with distal ends of dielectric 152 exposed from top encapsulant outer side 131, it is contemplated and understood that distal ends of dielectric 152 can be at least partially covered by top encapsulant 130 and openings in top encapsulant 130 can be provided to expose the distal ends of molded antenna feed structures 151a. Antenna patterns 153a or 153b can then extend into the openings to couple with the distal ends of molded antenna feed structures 151a.

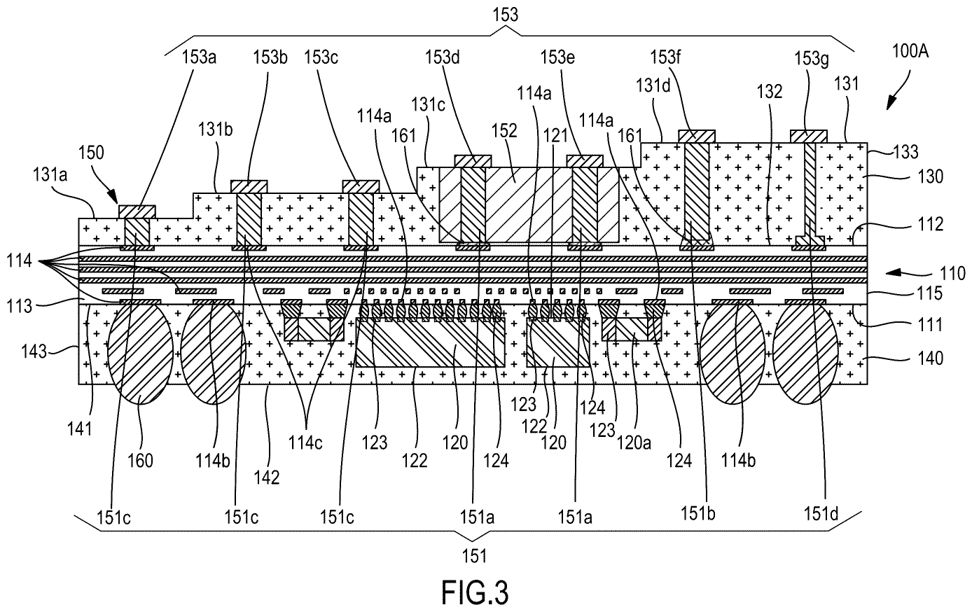

FIG. 3 shows a cross-sectional view of an example electronic device 100A. In the present example, electronic device 100A is provided in an example AiP/AoP configuration. Electronic device 100A of FIG. 3 has some similarity in construction to electronic device 100 of FIG. 1 and such similarity will not be repeated here. In this regard, only the distinctions between the two electronic devices will be discussed hereinafter.

In electronic device 100A, top encapsulant 130 and antennas 150 are provided in forms of steps, such as steps 131a, 131b, 131c, and 131d. In the example shown in FIG. 3, the thicknesses of steps 131a-131d gradually increase from one side of electronic device 100A to the opposite side. In some examples, top encapsulant outer side 131 on which antenna patterns 153a-153g are provided can be provided approximately in forms of steps 131a, 131b, 131c, and 131d. In some examples, the thicknesses or lengths of antenna feed structures 151a-151d can be in forms that gradually increase along the width direction (for example, left to right in the example of FIG. 3) of substrate 110. Steps 131a, 131b, 131c, and 131d can comprise or be referred to as stepped recessed regions, stepped regions, recesses, or stepped recesses each comprising a lower side that extends inward from top encapsulant outer side 131 to a different depth. The lower sides are configured to receive an antenna pattern. Steps 131a, 131b, 131c, and 131d are one example of a plurality of recessed regions extending inward from top encapsulant outer side 131.

In some examples, step 131a is an example of a first recessed region that defines a first step, step 131b is an example of a second recessed region that defines a second step, step 131c is an example of a third recessed region that defines a third step, and step 131d is an example where top encapsulant outer side 131 defines a fourth step.

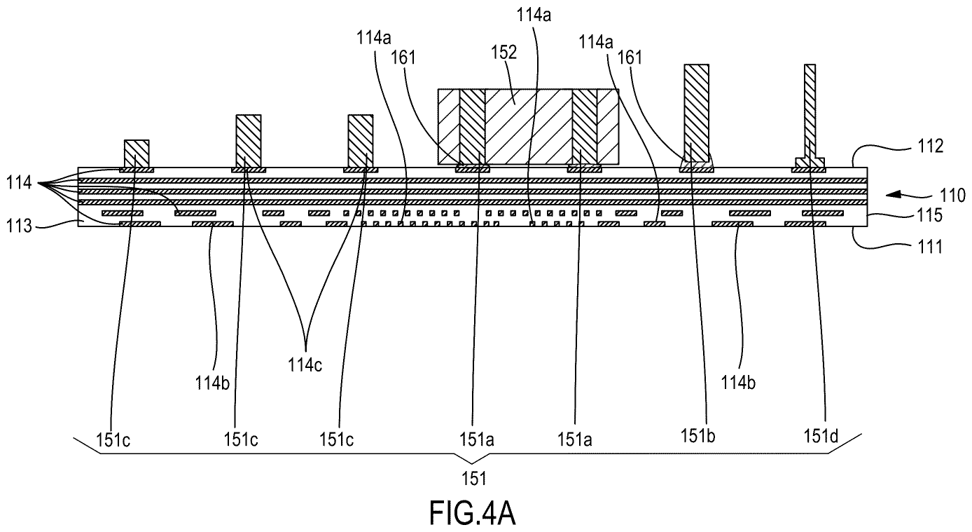

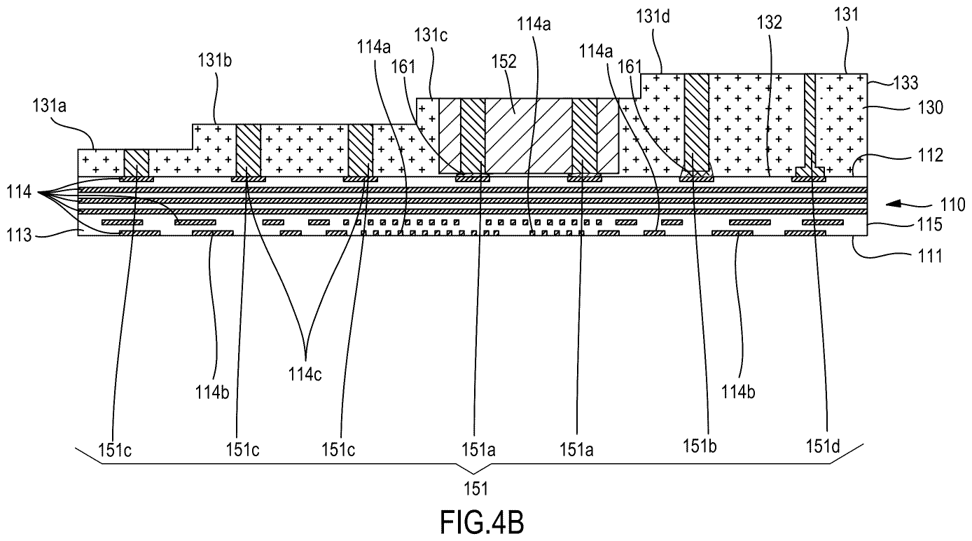

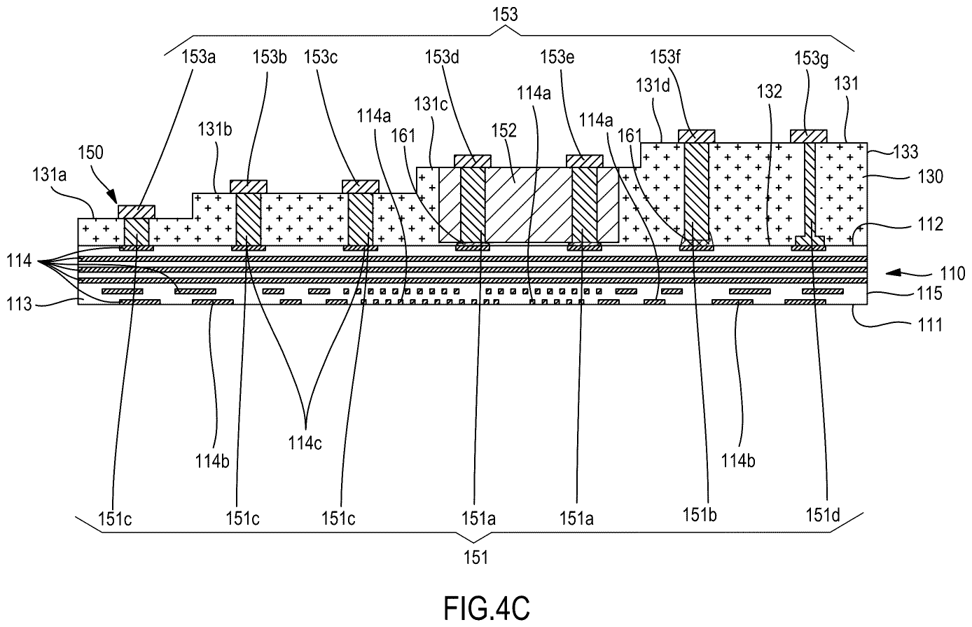

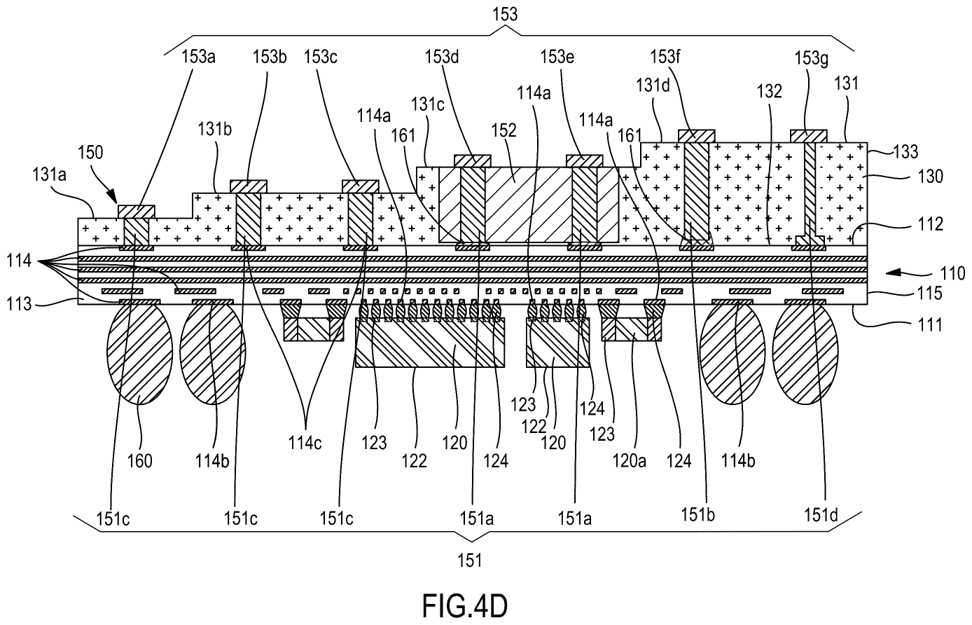

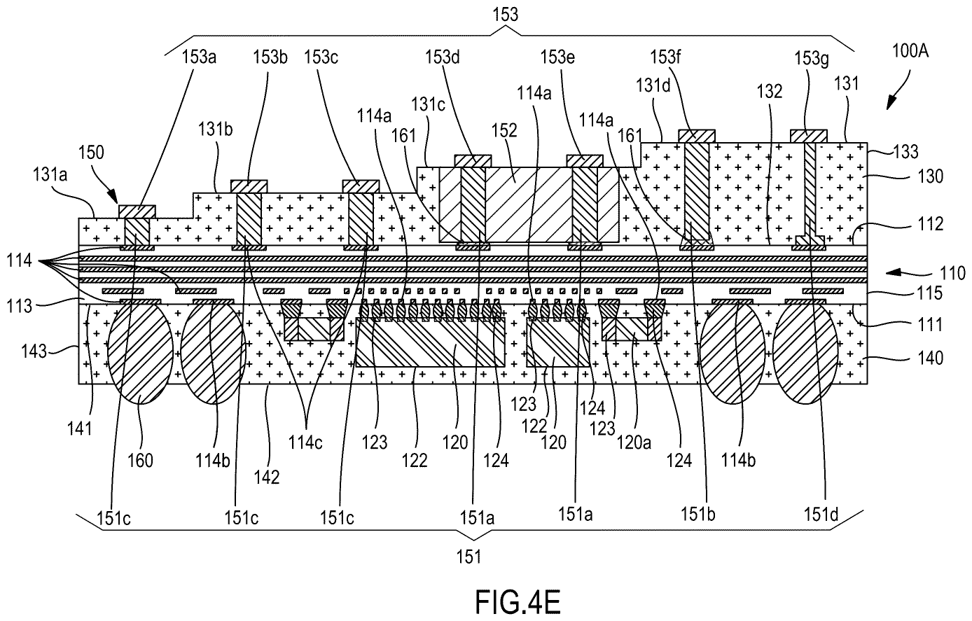

FIGS. 4A, 4B, 4C, 4D, and 4E show cross-sectional views of an example method for manufacturing an electronic device including, for example, electronic device 100A. The method of manufacturing described in FIGS. 4A to 4E has some similarity to the method of manufacture of FIGS. 2A to 2E and such similarity will not be repeated here. In this regard, only the distinctions between the methods will be discussed hereinafter.

FIG. 4A shows a cross-sectional view of electronic device 100A at an early stage of manufacture. In the example shown in FIG. 4A, substrate 110 can be provided in a manner similar to the step of providing substrate 110 as described above in FIG. 2A. Antenna feed structures 151 can then be provided on second side 112 of substrate 110 before electronic components 120, electronic components 120a, or external interconnects 160 are provided on first side 111 of substrate 110. In some examples, at least one of antenna feed structures 151 can be provided on second side 112 of substrate 110 before providing any components on first side 111 of substrate 110.

In the present example, antenna feed structures 151 can include molded antenna feed structures 151a, which are covered by dielectric 152, preformed pillar antenna feed structures 151b, plated pillar antenna feed structures 151c, or conductive wire antenna feed structure 151d. In some examples, proximate ends of antenna feed structures 151 are coupled to antenna terminals 114c adjacent to first side 111 of substrate 110. In some examples, proximate ends of molded antenna feed structures 151a or preformed pillar antenna feed structures 151b are coupled to antenna terminals 114c with conductive interface material 161, such as a solder. In the present example, molded antenna feed structures 151a are an example of a molded antenna feed structure having a plurality of molded antenna feed structures 151a within a single or integrated dielectric 152.

FIG. 4B shows a cross-sectional view of electronic device 100A at a later stage of manufacture. In some examples, top encapsulant 130 can be provided over antenna feed structures 151 and second side 112 and of substrate 110. In the example shown in FIG. 4B, top encapsulant 130 is provided before providing components for the bottom assembly can first be provided over second side 112 of substrate 110. In some examples, top encapsulant 130 can cover and/or contact second side 112 of substrate 110 and antenna feed structures 151 (or dielectric 152 of molded antenna feed structure 151a). Top encapsulant 130 can comprise top encapsulant outer side 131, a top encapsulant inner side 132 opposite to top encapsulant outer side 131, and a top encapsulant lateral side 133 connecting top encapsulant outer side 131 to top encapsulant inner side 132. In the present example, top encapsulant 130 comprises a thickness that varies across its lateral width in the form of steps 131a, 131b, 131c, and 131d. In accordance with the present description, this variation in thickness can be determined, for example, based on the frequency of operation of different antennas 150 of electronic device 100A.

Top encapsulant 130 can comprise or be referred to as an epoxy molding compound, a resin, a filler-reinforced polymer, a B-stage compression film, or a gel. In some examples, the encapsulant of top encapsulant 130 and dielectric 152 of molded antenna feed structures 151a can comprise similar or different materials. In some examples, top encapsulant 130 can be provided by compression molding, transfer molding, liquid encapsulant molding, vacuum lamination, paste printing, or film-assisted molding. For example, compression molding can be a method in which a fluidic resin is supplied into a mold in advance and then electronic device 100A is placed into the mold to cure the fluidic resin, and transfer molding can be a method in which a fluidic resin is supplied from a gate (supply port) of a mold to the area around electronic device 100 and cured. In some examples, the upper profile or topography of top encapsulant 130 can be provided in-situ during the molding process. For example, the upper profile can be provided as part of the upper mold cavity that corresponds to the step profile of top encapsulant 130 in electronic device 100A. In other examples, laser thinning or photolithographic and etching/milling processes can be used to provide the upper profile of top encapsulant 130. For example, after top encapsulant 130 is provided, an etch mask can be provided and patterned to include openings where steps 131a, 131b, and 131c are to be formed. After the openings are provided, portions of top encapsulant 130 can be chemically or physically removed to form the steps.

FIG. 4C shows a cross-sectional view of electronic device 100A at a later stage of manufacture. In the present example, antenna patterns 153 can be provided over top encapsulant outer side 131 and coupled to distal ends of antenna feed structures 151. In the example shown in FIG. 4C, antenna patterns 153 can be provided before providing components for the bottom assembly are provided over first side 111 of substrate 110. In some examples, antenna pattern 153a is provided over step 131a and is coupled to the distal end of a first plated pillar antenna feed structure 151c; antenna pattern 153b is provided over step 131b and is coupled to the distal end of a second plated pillar antenna feed structure 151c; antenna pattern 153c is also provided over step 131b and is coupled to the distal end of a third plated pillar antenna feed structure 151c; antenna pattern 153d is provided over step 131c and is coupled to a distal end of a first molded antenna feed structure 151a; antenna pattern 153e is also provided over step 131c and is coupled to the distal end of a second molded antenna feed structure 151a; antenna pattern 153f is provided over step 131d and is coupled to the distal end of preformed pillar antenna feed structure 151b; and antenna pattern 153g is also provided over step 131d and is coupled to the distal end of conductive wire antenna feed structure 151d. In the present example step 131d is located at top encapsulant outer side 131.

In some examples, antenna pattern 153b and antenna pattern 153c positioned on step 131b can be separate antenna patterns or can be portions of the same antenna pattern. In the example where antenna pattern 153b and antenna pattern 153c are portions of the same antenna pattern, one of first and second plated pillar antenna feed structures 151c can be a signal feed and the other one can be ground feed. This configuration can also apply, for example, to antenna pattern 153d and antenna pattern 153e positioned on step 131c or to antenna pattern 153f and antenna pattern 153g position on step 131d.

FIG. 4D shows a cross-sectional view of electronic device 100A at a later stage of manufacture. In the example shown in FIG. 4D, the components for the bottom assembly can be provided on first side 111 of substrate 110. Similar to the process described with FIG. 2B, electronic components 120, electronic components 120a, and external interconnects 160 can be coupled to first side 111 of substrate 110, Similar to the above, contact pads 123 of electronic components 120 and electronic components 120a can be coupled to component terminals 114a of substrate 110 via connectors 124, and external interconnects 160 can be coupled to external interconnect terminals 114b of substrate 110.

FIG. 4E shows a cross-sectional view of electronic device 100A at a later stage of manufacture. In the example shown in FIG. 4E, bottom encapsulant 140 can be provided over first side 111 of substrate 110, electronic components 120, electronic components 120a, and external interconnects 160. Bottom encapsulant 140 can cover and/or contact first side 111 of substrate 110, electronic components 120, electronic components 120a, and external interconnects 160. Bottom encapsulant 140 can comprise bottom encapsulant inner side 141, bottom encapsulant outer side 142 opposite to bottom encapsulant inner side 141, and lateral side 143 connecting bottom encapsulant inner side 141 to bottom encapsulant outer side 142. In the present example, bottom encapsulant inner side 141 is adjacent to first side 111 of substrate 110 and bottom encapsulant outer side 142 is distal to first side 111 of substrate 110. In some examples, portions of external interconnects 160 are exposed from bottom encapsulant outer side 142 and protrude outward (for example, downward or upward depending on the orientation of electronic device 100) from bottom encapsulant outer side 142.

While bottom encapsulant is shown covering the backside of electronic components 120 and electronic components 120, it is contemplated and understood that in some examples, one or more of electronic components 120 and/or one or more of electronic components 120a can be exposed through bottom encapsulant 140, such that electronic components 120 and/or electronic components 120a can be coplanar with bottom encapsulant outer side 142

Antenna feed structures 151, including, for example, antenna feed structures 151a-151d can comprise a conductor and are configured to transceive signals between electronic components 120, electronic components 120a, and antenna patterns 153, including, for example, antenna patterns 153a-153g through conductive structure 114 of substrate 110.

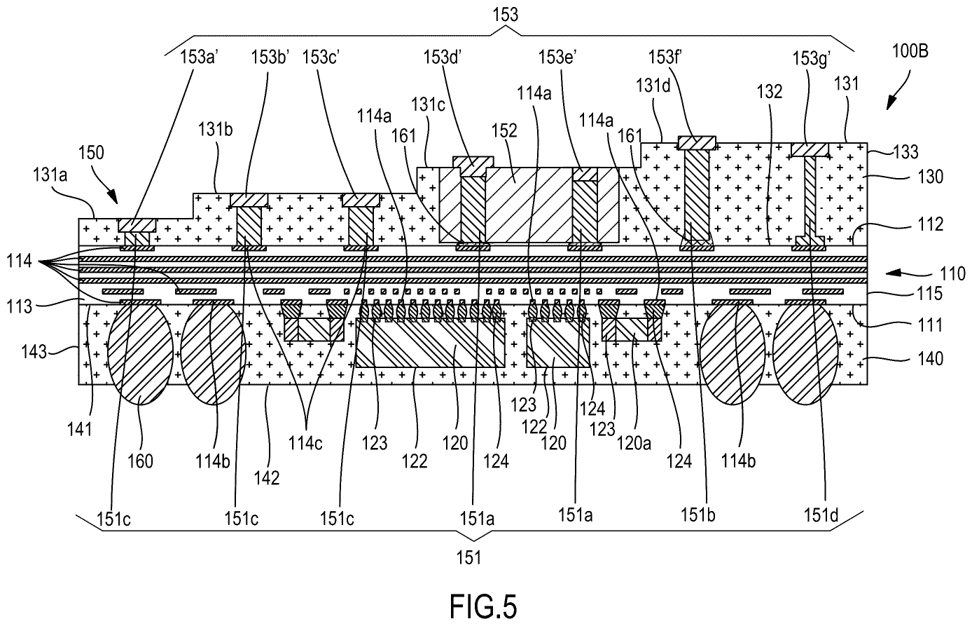

FIG. 5 shows a cross-sectional view of an example electronic device 100B. In the present example, electronic device 100B is provided in an example AiP/AoP configuration. Electronic device 100B of FIG. 5 has some similarity in construction to electronic device 100A of FIG. 3 and such similarity will not be repeated here. In this regard, only the distinctions between the two electronic devices will be discussed hereinafter.

In electronic device 100B, antenna patterns 153 can be configured differently that antenna patterns 153 described in FIG. 3. In some examples, antenna patterns 153 can comprise antenna patterns 153a′, antenna patterns 153b′, antenna patterns 153c′, and antenna patterns 153g′ (or portions thereof) that are embedded within top encapsulant 130. In some examples, the top sides of antenna patterns 153a′, antenna patterns 153b′, antenna patterns 153c′, and antenna patterns 153g′ (or portions thereof) can be coplanar with the top sides of steps 131a, 131b, or 131d where they are positioned in electronic device 100B. In some examples, antenna patterns 153 can include antenna pattern 153f′, which is partially embedded within top encapsulant 130 so that a portion of antenna pattern 153f′s extends or protrudes up step 131d. In some examples, top encapsulant 130 can be provided so that a portion of encapsulant 130 is over antenna feed structures 151. A masking and etching process can then be used to remove portions of top encapsulant 130 and provide patterned recesses above the distal ends of antenna feed structures 151. Antenna patterns 153a′, 153b′, 153c′, 153f′, and 153g′ can then be provided within the recesses in a similar manner as described in the formation of antenna patterns 153.

In some examples, the masking pattern for patterning top encapsulant 130 corresponds to the respective antenna patterns 153a′, 153b′, 153c′, 153f′, and 153g′ and is provided in the form of patterned recesses. The conductive materials for the antenna patterns can then be provided over top encapsulant 130 and within the patterned recesses. The conductive materials can be partially removed or planarized using an etch back process, a planarization process, combinations thereof, or other processes as known to one of ordinary skill in the art. For antenna pattern 153f′, another masking and etch process can be used to form the partially recessed pattern.

Antenna patterns 153 can also include antenna patterns 153d′ and 153e′ that are coupled to molded antenna feed structures 151a. In the present example, molded antenna feed structures 151a can be recessed below the exposed outer surface of dielectric 152 and antenna patterns 153d′ and 153e′ can make contact to molded antenna feed structures 151a within the recesses. In some examples, antenna pattern 153d′ can be partially recessed within dielectric 152. In some examples, antenna pattern 153e′ can be fully recessed within dielectric 152 (for example, no portion of antenna pattern 153e′ extends out of the recess to overlap onto the exposed outer surface of dielectric 12) so that a top side that is coplanar with the exposed outer surface of dielectric 152. In some examples, the distal ends of molded antenna feed structures 151a can be recessed after dielectric 152 is exposed from top encapsulant 130. In other examples, the distal ends of molded antenna feed structures 151a can be pre-formed as recessed before top encapsulant 130 is provided.

In summary, structures and methods have been described that relate to electronic devices using integrated antenna structures, such as multi-band AiP or AoP structures. More particularly, structures and methods have been described that include a recessed or stepped top encapsulant structure. The top encapsulant structure can be over a substrate and can cover antenna feed structures. Antenna patterns can be provided within the recesses or on the steps and can be coupled to different configurations of the antenna feed structures to provide different antennas. The characteristics of the antennas can be modified by varying the thickness of the top encapsulant structure and by adjusting the heights of the antenna feed structures to facilitate the design of a multi-band antenna configuration in a single electronic device or a single package structure. The structures and methods and structures described provide improved grounding, improved beam control, and better separation between the bands for improved inter-band separation performance. In addition, the structures and methods described incorporate existing manufacturing techniques, which saves on costs.

In some examples, the antenna feed structures can include molded antenna feed structures, preformed pillar antenna feed structures, plated pillar antenna feed structures, or conductive wire antenna feed structures. The antenna feed structures can be configured as signal lines or ground lines. In some examples, the antenna patterns can be located on top of the top encapsulant structure. In some examples, the antenna patterns can be embedded within the top encapsulant structure.

In some examples, electronic components can be coupled to the substrate and the antenna feed structures.

The present disclosure includes reference to certain examples, however, it will be understood by those skilled in the art that various changes may be made and equivalents may be substituted without departing from the scope of the disclosure. Modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a substrate comprising:
a substrate first side;
a substrate second side opposite to the substrate first side; and
a conductive structure;
an antenna structure comprising:
antenna feed structures coupled to the substrate first side; and
antenna patterns each coupled to one of the antenna feed structures;
a top encapsulant covering the antenna feed structures and the substrate first side and comprising:
a top encapsulant outer side; and
a first recess extending inward from the top encapsulant outer side, the first recess comprising a first recess lower side below the top encapsulant outer side, wherein:
the antenna feed structures comprise a first antenna feed structure and a second antenna feed structure; and
the antenna patterns comprise:
a first antenna pattern adjacent to the first recess lower side and coupled to the first antenna feed structure; and
a second antenna pattern adjacent to the top encapsulant outer side and coupled to the second antenna feed structure; and
electronic components coupled to the substrate at the substrate second side and coupled to the antenna feed structures.

2. The electronic device of claim 1, further comprising:
external interconnects; and
a bottom encapsulant covering the electronic components, the substrate second side, and portions of the external interconnects.

3. The electronic device of claim 1, wherein:
the first antenna feed structure comprises a molded antenna feed structure comprising a first conductive feed portion embedded within a dielectric.

4. The electronic device of claim 3, wherein:
the molded antenna feed structure comprises a second conductive feed portion embedded within the dielectric; and
the antenna patterns comprises a third conductive pattern coupled to the second conductive feed portion.

5. The electronic device of claim 3, wherein:
the molded antenna feed structure comprises a second conductive feed portion embedded with the dielectric and coupled the first antenna pattern.

6. The electronic device of claim 1, wherein:
the first antenna feed structure comprises a preformed pillar antenna feed structure.

7. The electronic device of claim 1, wherein:
the first antenna feed structure comprises a plated pillar antenna feed structure.

8. The electronic device of claim 1, wherein:
the first antenna feed structure comprises a conductive wire antenna feed structure.

9. The electronic device of claim 1, wherein:
the first antenna feed structure and the second antenna feed structure comprise different antenna feed structures.

10. The electronic device of claim 1, further comprising:
a plurality of recesses extending inward from the top encapsulant outer side comprising:
the first recess, wherein the first recess lower side extends below the top encapsulant outer side to a first depth; and
a second recess extending inward from the top encapsulant outer side, the second recess comprising a second recess lower side extending below the top encapsulant outer side to a second depth different than the first depth;
a third antenna feed structure coupled to the substrate first side and covered by the top encapsulant; and
a third antenna pattern adjacent to the second recess lower side and coupled to the third antenna feed structure, wherein the electronic device comprises a multi-band antenna.

11. An electronic device, comprising:
a substrate comprising:
a substrate first side;
a substrate second side opposite to the substrate first side;
a dielectric structure; and
a conductive structure within the dielectric structure;
a plurality of antenna feed structures coupled to the conductive structure at the substrate first side and comprising a first antenna feed structure, a second antenna feed structure, and a third antenna feed structure;
a top encapsulant covering the plurality of antenna feed structures and the substrate first side and comprising:
a top encapsulant outer side; and
a plurality of recessed regions extending inward from the top encapsulant outer side and comprising a first recessed region comprising a first lower side, a second recessed region comprising a second lower side, and a third recessed region comprising a third lower side;
a plurality of antenna patterns comprising a first antenna pattern adjacent to the first lower side and coupled to the first antenna feed structure, a second antenna pattern adjacent to the second lower side and coupled to the second antenna feed structure, a third antenna pattern adjacent to the third lower side and coupled to the third antenna feed structure;
electronic components coupled to the conductive structure at the substrate second side; and
a bottom encapsulant covering the electronic components and the substrate second side.

12. The electronic device of claim 11, wherein:
the plurality of recessed regions comprises steps, each step comprising a thickness that increases from a first side of the electronic device to an opposing second side of the electronic device, wherein:
the first recessed region defines a first step;
the second recessed region defines a second step;
the third recessed region defines a third step; and
the top encapsulant outer side defines a fourth step.

13. The electronic device of claim 12, wherein:
the plurality of antenna feed structures comprises a fourth antenna feed structure; and
the plurality of antenna patterns comprises a fourth antenna pattern on the fourth step and coupled to the fourth antenna feed structure.

14. The electronic device of claim 11, wherein:
one or more of the first antenna pattern, the second antenna pattern, or the third antenna pattern is embedded within the top encapsulant.

15. The electronic device of claim 11, further comprising:
external interconnects coupled to the conductive structure at the substrate second side, wherein the bottom encapsulant covers first portions of the external interconnects and second portions of the external interconnects protrude outward from the bottom encapsulant.

16. A method of manufacturing an electronic device, comprising:
providing a substrate comprising:
a substrate first side;
a substrate second side opposite to the substrate first side;
a dielectric structure; and
a conductive structure within the dielectric structure;
providing a plurality of antenna feed structures coupled to the conductive structure at the substrate first side and comprising a first antenna feed structure, a second antenna feed structure, and a third antenna feed structure;
providing a top encapsulant covering the plurality of antenna feed structures and the substrate first side and comprising:
a top encapsulant outer side; and
a plurality of recessed regions extending inward from the top encapsulant outer side and comprising a first recessed region comprising a first lower side, a second recessed region comprising a second lower side, and a third recessed region comprising a third lower side;
providing a plurality of antenna patterns comprising a first antenna pattern adjacent to the first lower side and coupled to the first antenna feed structure, a second antenna pattern adjacent to the second lower side and coupled to the second antenna feed structure, a third antenna pattern adjacent to the third lower side and coupled to the third antenna feed structure;
providing electronic components coupled to the conductive structure at the substrate second side; and
providing a bottom encapsulant covering the electronic components and the substrate second side.

17. The method of claim 16, wherein:
providing the top encapsulant comprises providing the plurality of recessed regions comprising steps, each step comprising a thickness that increases from a first side of the electronic device to an opposing second side of the electronic device, wherein:
the first recessed region defines a first step;
the second recessed region defines a second step;
the third recessed region defines a third step; and
the top encapsulant outer side defines a fourth step.

18. The method of claim 17, wherein:
providing the plurality of antenna feed structures comprises providing a fourth antenna feed structure; and
providing the plurality of antenna patterns comprises providing a fourth antenna pattern on the fourth step and coupled to the fourth antenna feed structure.

19. The method of claim 16, wherein:
providing the plurality of antenna patterns comprises providing one or more of the first antenna pattern, the second antenna pattern, or the third antenna pattern embedded within the top encapsulant.

20. The method of claim 16, further comprising:
providing external interconnects coupled to the conductive structure at the substrate second side, wherein:
providing the bottom encapsulant comprising covering first portions of the external interconnects and second portions of the external interconnects protrude outward from the bottom encapsulant.
